(19) United States
(12) Patent Application Publication
(10) Pub. No.: US 2009/0014761 A1
(43) Pub. Date: Jan. 15, 2009

(54) IMAGE SENSOR PIXEL AND FABRICATION METHOD THEREOF

(75) Inventor: Cheol Soo Park, Jeju-do (KR)

Correspondence Address: CANTOR COLBURN, LLP, 20 Church Street, 22nd Floor, Hartford, CT, 06103, US

(73) Assignees: Cheol Soo PARK, Jeju-si (KR); SILICONFILE TECHNOLOGIES INC., Seoul (KR)

(21) Appl. No.: 11/993,311

(22) PCT Filed: Jun. 14, 2006
(86) PCT No.: PCT/KR06/02274

§ 371 Date: Dec. 20, 2007

(30) Foreign Application Priority Data
Jun. 23, 2005 (KR) 10-2005-0054481

(51) Int. Cl. H01L 31/113; H01L 21/00

(52) U.S. Cl. 257/292; 438/57; 257/E31.083; 257/E21.001

(57) ABSTRACT

Provided is an image sensor pixel in which a specific or entire area of a field oxide layer inside the pixel can be used as a photodiode so as to increase a fill factor, and a fabrication method thereof. The image sensor pixel includes: a photodiode which is buried inside a semiconductor substrate; and pixel transistors which are formed after the photodiode is formed. In addition, the image sensor pixel includes: pixel transistors; a field oxide layer which separates the pixel transistors; and a photodiode which is located at the lower portion in a specific or entire area of the field oxide layer. In addition, the fabrication method includes: (a) forming a trench region in a specific area of a semiconductor substrate; (b) forming a photodiode which includes at least a portion of the trench region; and (c) forming pixel transistor, after the photodiode is formed. Accordingly, a surface area of a photodiode increases, thereby improving a fill factor and photosensitivity. In addition, in a unit pixel of an image sensor, the entire pixel area becomes a photodiode region except for a region where transistors are formed, thereby maximizing the fill factor.

### TECHNICAL FIELD

The present invention relates to a structure of an image sensor pixel and a fabrication method thereof, and more particularly, to an active pixel type complementary metal oxide semiconductor (CMOS) image sensor including an active element of transistors.

### BACKGROUND ART

An image sensor captures an image by using a semiconductor's characteristic which is responsive to an external energy (for example, photon). Each subject existing in the nature generates light having its unique energy value for example in terms of wavelength. The light generated from each subject is sensed by an image sensor pixel so as to be converted into an electrical value. An example of the image sensor pixel is a 4-transistor CMOS active pixel.

FIG. 1 is a circuit diagram of an image sensor which is composed of four transistors 110 to 140 and one photodiode 190. The circuit of the image sensor operates as follows. First, the photodiode 190 is reset in response to RX and TX signals for a reset period. Thereafter, light condensed at the photodiode 190 is converted into an electrical signal to be sent to an output node Vout via a transmission transistor 110, a driver transistor 130, and a selection transistor 140.

FIG. 2 is a plan view of a CMOS image sensor formed on a semiconductor substrate. FIG. 3 is a cross-sectional view of the plan view of FIG. 2, cut along the X-X′ line.

The structure of the conventional image sensor pixel will now be described with reference to FIGS. 2 and 3.

A driver transistor 130 and a selection transistor 140 of FIG. 2 are not shown in FIG. 3 due to the cutting direction. Like reference numerals denote like elements in FIGS. 2 and 3.

An image sensor needs to be sensitive to an optical energy. Thus, a semiconductor substrate 101 may be an epitaxial growth substrate having a low leakage current.

A node between a transmission transistor 110 and a reset transistor 120 is connected to a gate of a driver transistor 130 by a metal layer 125 through a contact layer.

A P-well protection layer 150 prevents a P-well 151 of FIG. 3 from forming on a region where the photodiode 190 will be formed.

A PDN layer 160 is formed by implanting an N-type impurity to a cathode of the photodiode 190. A PDP layer 180 is formed by implanting a P-type impurity to an anode of the photodiode 190. A PN junction is formed in a region where the PDN layer 160 and the PDP layer 180 overlap from each other, thereby forming an area of the photodiode 190.

Although not shown in FIG. 3, the photodiode 190 and a source region of the transmission transistor 110 are connected by a PDC layer 185.

Meanwhile, with the development of a semiconductor technology, image sensor pixels as well as photodiodes have been downsized. In addition, the number of an insulation layer and the number of a metal wire layer, which overlap on a semi-conductor substrate, increase. Thus, a distance between a pixel surface and a photodiode increases, thereby reducing light condensed at the photodiode 190 of the pixel. As a result, the quality of the image sensor deteriorates.

To solve the above problems, in the conventional method, a micro lens in the form of a convex lens is formed on a color filter that is the uppermost layer of a formed pixel, so that an incident light entering to the image sensor can be condensed, thereby increasing light reaching the photodiode 190.

It has generally been found that a better image quality can be obtained in an image sensor when a large photodiode is used to provide a sufficient amount of light. A fill factor is defined as an area which is occupied by a photodiode over the entire pixel area. A pixel characteristic may be estimated using the fill factor.

As shown in FIG. 2, in the conventional active pixel, since the photodiode 190 and the transistors 110 to 140 have to be arranged on one plane, the fill factor is only 6-16%. As a result, photosensitivity deteriorates, a distance between adjacent pixels decreases, and crosstalk becomes serious, thereby generating much noise.

Furthermore, referring to FIG. 2, the transistors 110 to 140 and a field oxide layer 195 are formed on a specific region of a unit pixel, except for a region for forming the photodiode 190. This is because the transistors 110 to 140 have to be formed first, and then the field oxide layer 195 is used to separate the transistors 110 to 140 from one another.

Accordingly, in the present invention, a lower region of the field oxide layer 195 except for a region occupied by the photodiode 190 and the transistors 110 to 140 in a unit pixel of an image sensor can be effectively used.

### DISCLOSURE OF INVENTION

Technical Problem

In order to solve the aforementioned problems, an object of the present invention is to provide an image sensor pixel in which an area of a photodiode can increase within a limited pixel size, and a fabrication method thereof.

Another object of the present invention is to provide an image sensor pixel in which a photodiode is formed on a trench region of a semiconductor substrate so as to achieve an effective fill factor.

Another object of the present invention is to provide an image sensor pixel which minimizes a crosstalk phenomenon between adjacent pixels.

Another object of the present invention is to provide an image sensor pixel in which a photodiode can be constructed to occupy larger area in a limited pixel size, thereby obtaining a good sensitivity.

Another object of the present invention is to provide an image sensor pixel which does not require a micro lens.

Another object of the present invention is to provide an image sensor pixel by which an electronic device employing the image sensor pixel can improve its performance, and a customer can obtain cost competitiveness.

Technical Solution

According to an aspect of the present invention, there is provided an image sensor pixel comprising: a photodiode which is buried inside a semiconductor substrate; and pixel transistors which are formed after the photodiode is formed.

According to another aspect of the present invention, there is provided an image sensor pixel comprising: pixel transistors; a field oxide layer which separates the pixel transistors; and a photodiode which is located at the lower portion in a specific or entire area of the field oxide layer. According to another aspect of the present invention, there is provided a fabrication method of an image sensor pixel comprising: (a) forming a trench region in a specific area of a semiconductor substrate; (b) forming a photodiode which includes at least a portion of the trench region; and (c) forming pixel transistors after the photodiode is formed.

### BRIEF DESCRIPTION OF THE DRAWINGS

FIG. 1 is a circuit diagram of a CMOS image sensor having a 4-TR structure;

FIG. 2 is a plan view of a conventional CMOS image sensor;

FIG. 3 is a cross-sectional view of a conventional CMOS image sensor;

FIG. 4 is a plan view of a pixel layer according to an embodiment of the present invention;

FIG. 5 is a plan view of another pixel layer according to an embodiment of the present invention;

FIG. 6 is a cross-sectional view of a pixel including a photodiode connection layer according to an embodiment of the present invention;

FIG. 7 is a cross-sectional view of a pixel including a transistor layer according to an embodiment of the present invention;

FIG. 8 is a cross-sectional view of FIG. 4, cut along the X-X′ line;

FIG. 9 is a cross-sectional view of FIG. 5, cut along the X-X′ line;

FIG. 10 is a cross-sectional view of FIG. 6, cut along the X-X′ line;

FIG. 11 is a cross-sectional view of FIG. 7, cut along the X-X′ line;

FIG. 12 is a cross-sectional view of a pixel including a metal layer;

FIG. 13 is a simplified view of FIG. 2, and illustrates an emphasized area of a photodiode in a conventional pixel; and

FIG. 14 is a plan view illustrating an emphasized area of a photodiode in a pixel according to an embodiment of the present invention.

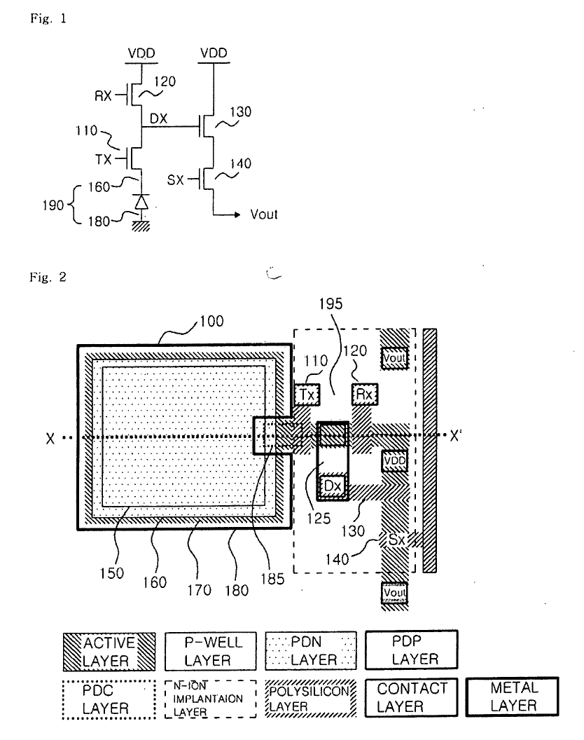

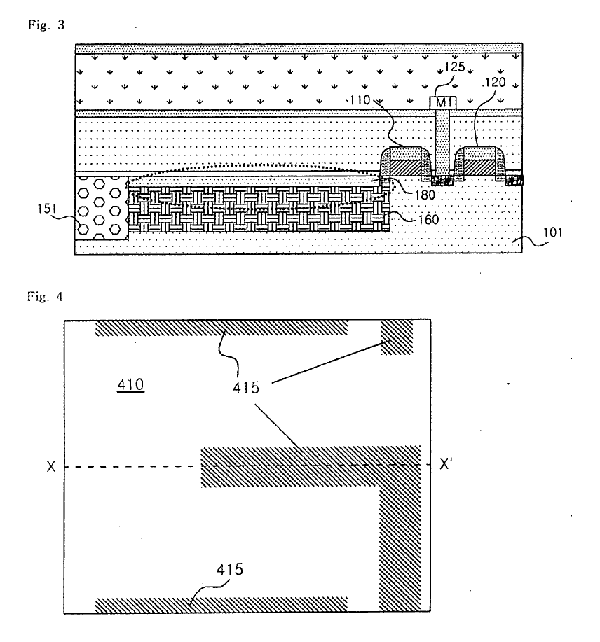

### BEST MODE FOR CARRYING OUT THE INVENTION

The attached drawings for illustrating exemplary embodiments of the present invention are referred to in order to gain a sufficient understanding of the present invention, the merits thereof, and the objectives accomplished by the implementation of the present invention.

Hereinafter, the present invention will be described in detail by explaining exemplary embodiments of the invention with reference to the attached drawings. Like reference numerals in the drawings denote like elements.

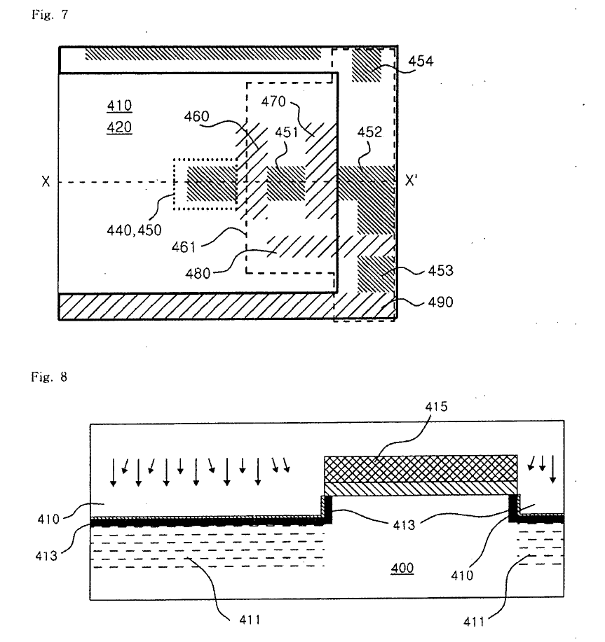

FIGS. 4 to 7 are plan views illustrating a fabrication method of an image sensor pixel according to an embodiment of the present invention. FIGS. 8 to 12 are cross-sectional views of FIGS. 4 to 7, cut along the X-X direction. The following descriptions will focus on a key aspect of the present invention rather than explaining all aspects of the fabrication method, and this will be understood by those skilled in the art.

Now, a fabrication method of an image sensor pixel according to an embodiment of the present invention will be descried with reference to FIGS. 4 and 8.

A trench region 410 of FIG. 8 on a portion of a semiconductor substrate 400 is etched by using a field mask 415. The semiconductor substrate 400 may use an epitaxial growth wafer for a low leakage characteristic of a semiconductor image sensor.

A first electrode 411 of a photodiode is formed on the trench region 410 by ion implanting. In this case, if a P-type semiconductor substrate is used, the first electrode 411 is implanted with an N-type ion, thereby forming a negative electrode.

A positive electrode 413 of the photodiode is formed by implanting a P-type ion with a depth smaller than the negative electrode 411 of the photodiode. The P-type ion is implanted by using a tilted ion implantation, so that a P-type region can be well formed on lateral surfaces of the trench formed within the semiconductor substrate 400.

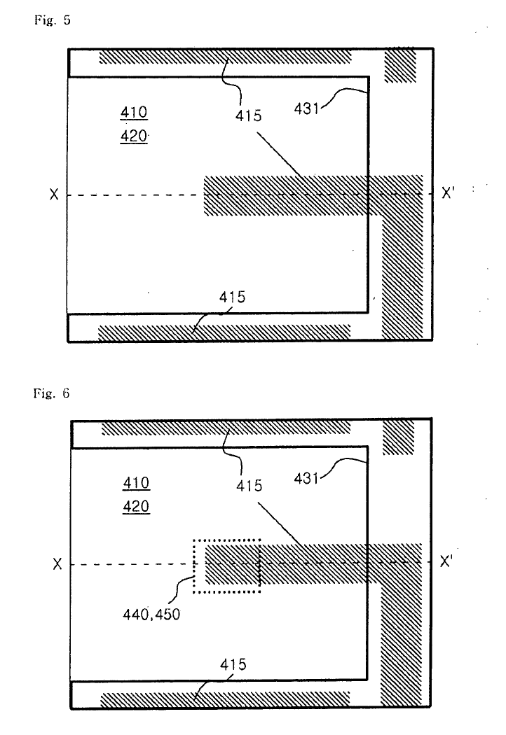

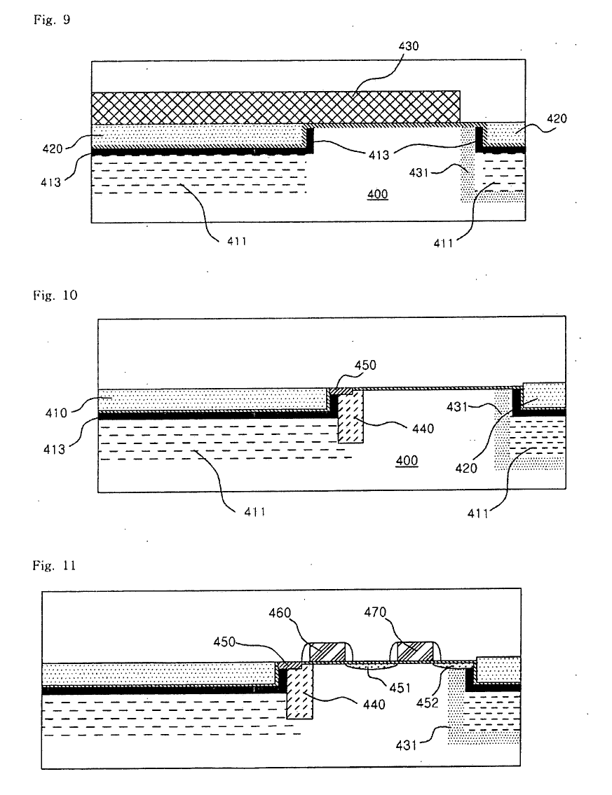

A field oxide layer 420 is formed with an appropriate thickness, and chemical mechanical polishing (CMP) is then carried out so that the field oxide layer 420 remains only on the trench region 410. Referring to FIG. 5, the field oxide layer 420 overlaps with the trench region 410 in a state that the field oxide layer 420 remains on the trench region 410. A P-well layer is indicated by reference numeral 431 of FIG. 5. Referring to FIG. 9, a photo resist 430 is applied to form a P-well 431.

After the P-well 431 is formed by ion implanting, photodiode connection regions 440 and 450 for connecting the photodiode with a transistor arc forncd by ion implanting. As shown in FIG. 6, two times of ion implanting are independently carried out in order to form the photodiode connection regions 440 and 450, preferably with different ion energy levels and depths. However, if necessary, the ion implanting may be carried out only one time.

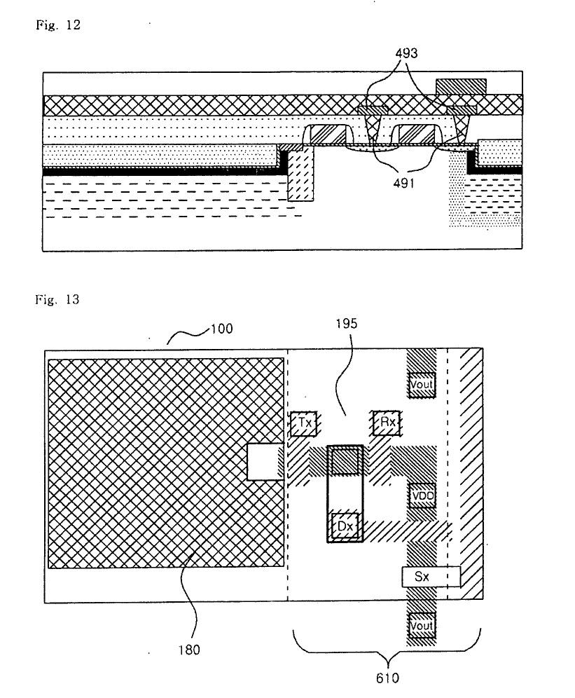

Next, as shown in FIGS. 7 and 11, pixel transistors 460, 470, 480, and 490 are formed, and active regions 451, 452, 453, and 454 are formed through ion implanting by using an N-type ion implant mask 461.

The reason why the active regions 451, 452, 453, and 454 are indicated by new reference numerals is that only regions existing inside the N-type ion implant mask 461 among regions defined as the field mask 415 of FIGS. 4 to 6 become an active region by ion implanting, and the rest of regions except for the above regions are not converted into the active region since the field oxide layer 420 interferes the ion implanting.

Next, the pixel transistors 460, 470, 480, and 490 are connected properly by using a metal contact layer and a metal layer, thereby forming the transmission transistor 460, the reset transistor 470, the driver transistor 480, and the selection transistor 490, respectively (see FIG. 12).

The connecting process is equal or similar to that of a typical CMOS transistor fabrication, and will be understood those skilled in the art. Thus, detailed description thereof will be omitted.

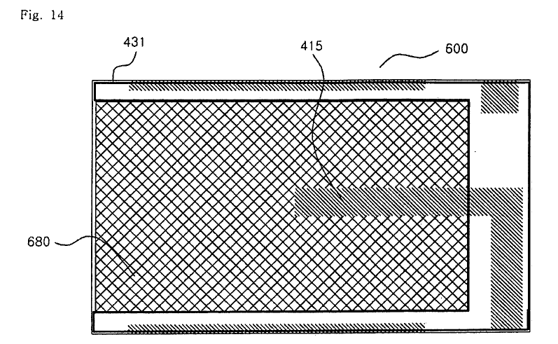

FIG. 13 is a simplified view of FIG. 2, and illustrates a conventional image sensor pixel 100, in which a region of a photodiode 180 and the rest of region 610 including transistors are emphasized.

FIG. 14 is a simplified view of FIG. 7, and illustrates an image sensor pixel 600 according to an embodiment of the present invention, in which a region of a photodiode 680 is emphasized. Here, a region except for a p-well layer 431 and an active layer 415 becomes the region for the photodiode 680, thereby maximizing the fill factor.

Advantages of the present invention will become apparent by comparing FIGS. 13 and 14.

In the prior art of FIG. 13, transistors separated by an oxide layer 195 are formed before a photodiode 180 is formed. Thus, the photodiode 180, the field oxide layer 195, and the transistors occupy the entire pixel area.

On the other hand, in the present invention of FIG. 14, after the photodiode 680 is formed on a trench region in the entire pixel 600, the field oxide layer 195 is formed at the upper portion of the photodiode 680, and transistors are formed on the rest of regions. That is, a unit pixel only includes a region for the photodiode 680 and the rest of regions 431 and 415. As a result, a region conventionally used for the field oxide layer 195 can be used for the photodiode 680, thereby maximizing the fill-factor.

According to an embodiment of the present invention shown in FIGS. 4 to 7, the photodiode is formed in the shape of “U”, so that the trench region can occupy most of the pixel area, thereby increasing the fill-factor.

Although not shown, the photodiode may be formed in the shape of “L”. Such shapes vary depending on the positions of the photodiode and the pixel transistors. The photodiode may be formed in a buried form by using a shallow trench notch, and this is included in the scope of the present invention.

According to the present invention, a surface area of a photodiode increases, thereby improving a fill factor and photosensitivity.

In addition, in a unit pixel of an image sensor, the entire pixel area becomes a photodiode region except for a region where transistors are formed, thereby maximizing the fill factor.

In addition, a micro lens is no longer required since more light can be condensed, thereby providing economical benefit.

In addition, a crosstalk between adjacent pixels can be minimized due to a protruding structure of a photodiode, thereby increasing efficiency of an image sensor.

While the present invention has been particularly shown and described with reference to exemplary embodiments thereof, it will be understood by those skilled in the art that various changes in form and details may be made therein without departing from the spirit and scope of the present invention as defined by the appended claims.

1. An image sensor pixel comprising:
a photodiode which is buried inside a semiconductor substrate; and
pixel transistors which are formed after the photodiode is formed.

2. The image sensor pixel of claim 1, further comprising a trench region which is formed in a specific area of the semiconductor substrate.

3. The image sensor pixel of claim 2, further comprising a field oxide layer which is formed at the upper portion of the trench region.

4. An image sensor pixel comprising:
pixel transistors;
a field oxide layer which separates the pixel transistors; and
a photodiode which is located at the lower portion in a specific or entire area of the field oxide layer.

5. A fabrication method of an image sensor pixel, comprising:
forming a trench region in a specific area of a semiconductor substrate;
forming a photodiode which includes at least a portion of the trench region; and
forming pixel transistors after the photodiode is formed.

6. The fabrication method of claim 5, further comprising forming a field oxide layer at the upper portion of the trench region after the photodiode is formed.
